(19) United States
(12) Patent Application Publication
(10) Pub. No.: US 2022/0415652 A1
(43) Pub. Date: Dec. 29, 2022

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Daigo YAMAGUCHI, Toyama-shi (JP); Atsushi SANO, Toyama-shi (JP); Yoshitomo HASHIMOTO, Toyama-shi (JP)

(73) Assignee: Kokusai Electric Corporation, Tokyo (JP)

(21) Appl. No.: 17/897,618

(22) Filed: Aug. 29, 2022

Related U.S. Application Data
(63) Continuation of application No. PCT/JP2020/007979, filed on Feb. 27, 2020.

(51) Int. Cl. H01L 21/02; C23C 16/455; C23C 16/56; C23C 16/04; C23C 16/30

(52) U.S. Cl. CPC H01L 21/02337; C23C 16/455; C23C 16/56; C23C 16/045; C23C 16/30; H01L 21/02167

(57) ABSTRACT

A method for forming an oligomer-containing layer on a substrate and in a concave portion formed on the substrate by performing a cycle a predetermined number of times under a first temperature, the cycle including supplying a precursor gas to the substrate, and supplying first and second nitrogen- and hydrogen-containing gases to the substrate, so an oligomer including an element in at least one selected from the group of the precursor gas, and the first and second nitrogen-hydrogen-containing gasses, flowed in the concave portion, and (b) forming a film to fill the inside of the concave portion by post-treating the substrate, which has the oligomer-containing layer formed on the surface of the substrate and in the concave portion, under a second temperature not less than the first temperature, so that the oligomer-containing layer formed in the concave portion is modified to form the film.

### CROSS-REFERENCE TO RELATED APPLICATIONS

This application is a Bypass Continuation Application of PCT International Application No. PCT/JP2020/007979, filed on Feb. 27, 2020, the entire contents of which are incorporated herein by reference.

### BACKGROUND

The present disclosure relates to a method of processing a substrate, a method of manufacturing a semiconductor device, a substrate processing apparatus, and a recording medium.

### DESCRIPTION OF THE RELATED ART

As one of the processes of manufacturing a semiconductor device, a process of forming a film on a substrate by using a plurality of types of gases may be performed. In this case, a process of forming a film by using a plurality of types of gases to fill the inside of a concave portion provided on the surface of the substrate may be performed.

### SUMMARY

The present disclosure improves the characteristics of a film formed so as to fill a concave portion provided on a surface of a substrate.

According to one aspect of the present disclosure, there is provided a technique that includes:

(a) forming an oligomer-containing layer on a surface of a substrate and in a concave portion formed on the surface of the substrate by performing a cycle a predetermined number of times under a first temperature, the cycle including supplying a precursor gas to the substrate, supplying a first nitrogen- and hydrogen-containing gas to the substrate, and supplying a second nitrogen- and hydrogen-containing gas to the substrate, so that an oligomer including an element contained in at least one selected from the group of the precursor gas, the first nitrogen- and hydrogen-containing gas, and the second nitrogen- and hydrogen-containing gas is generated, grown, and flowed on the surface of the substrate and in the concave portion; and

(b) forming a film so as to fill the inside of the concave portion by performing a post-treatment to the substrate, which has the oligomer-containing layer formed on the surface of the substrate and in the concave portion, under a second temperature not less than the first temperature, so that the oligomer-containing layer formed on the surface of the substrate and in the concave portion is modified to form the film.

### BRIEF DESCRIPTION OF THE DRAWINGS

FIG. 1 is a schematic configuration view of a vertical process furnace of a substrate processing apparatus suitably used in each aspect of the present disclosure and is a longitudinal cross-sectional view of a process furnace portion.

FIG. 2 is a schematic configuration view of the vertical process furnace of the substrate processing apparatus suitably used in each aspect of the present disclosure and is a cross-sectional view of the process furnace portion taken along line A-A of FIG. 1.

FIG. 3 is a schematic configuration view of a controller of the substrate processing apparatus suitably used in each aspect of the present disclosure and is a block diagram of a control system of the controller.

FIG. 4 is a diagram illustrating a substrate processing sequence according to a first aspect of the present disclosure.

FIG. 5 is a diagram illustrating a substrate processing sequence according to a second aspect of the present disclosure.

FIG. 6 is a diagram illustrating a substrate processing sequence according to a third aspect of the present disclosure.

### DETAILED DESCRIPTION

First Aspect of the Present Disclosure

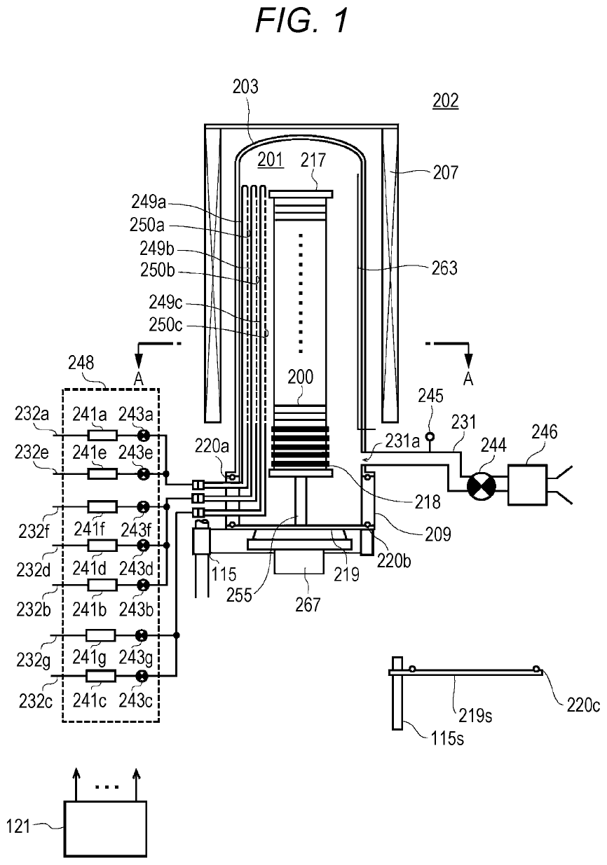

Hereinafter, the first aspect of the present disclosure will be described with reference to FIGS. 1 to 4.

(1) Configuration of Substrate Processing Apparatus

As illustrated in FIG. 1, a process furnace 202 includes a heater 207 serving as a heating mechanism (temperature regulator). The heater 207 has a cylindrical shape and is vertically installed by being supported on a holding plate. The heater 207 also functions as an activation mechanism (excitation section) configured to activate (excite) a gas with heat.

Inside the heater 207, a reaction tube 203 is disposed concentrically with the heater 207. The reaction tube 203 is made of, for example, a heat resistant material such as quartz (SiO₂) or silicon carbide (SiC), and is formed in a cylindrical shape with a closed upper end and an opened lower end. Under the reaction tube 203, a manifold 209 is disposed concentrically with the reaction tube 203. The manifold 209 is made of, for example, a metal material such as stainless steel (SUS), and is formed in a cylindrical shape with an opened upper end and an opened lower end. An upper end portion of the manifold 209 is configured to be engaged with a lower end portion of the reaction tube 203 so as to support the reaction tube 203. An O-ring 220a serving as a seal member is provided between the manifold 209 and the reaction tube 203. Similar to the heater 207, the reaction tube 203 is in a state of being installed vertically. A process vessel (reaction vessel) is mainly configured by the reaction tube 203 and the manifold 209. A process chamber 201 is formed in a cylindrical hollow portion of the process vessel. The process chamber 201 is configured such that a wafer 200 serving as a substrate can be accommodated. The wafer 200 is processed in the process chamber 201.

In the process chamber 201, nozzles 249a to 249c serving as first to third suppliers are provided to pass through a sidewall of the manifold 209. The nozzles 249a to 249c are also referred to as first to third nozzles. The nozzles 249a to 249c are made of, for example, a non-metal material that is a heat resistant material such as quartz or SiC. Gas supply pipes 232a to 232c are respectively connected to the nozzles 249a to 249c. The nozzles 249a to 249c are different nozzles from each other, and each of the nozzles 249a and 249c is provided adjacent to the nozzle 249b.

Mass flow controllers (MFCs) 241a to 241c acting as flow rate controllers (flow control section) and valves 243a to 243c acting as on-off valves are respectively provided in the gas supply pipes 232a to 232c in this order from the upstream side of gas flow. A gas supply pipe 232e is connected to the downstream side of the valve 243a of the gas supply pipe 232a. Gas supply pipes 232d and 232f are connected to the downstream side of the valve 243b of the gas supply pipe 232b. A gas supply pipe 232g is connected to the downstream side of the valve 243c of the gas supply pipe 232c. MFCs 241d to 241g and valves 243d to 243g are respectively provided in the gas supply pipes 232d to 232g in this order from the upstream side of gas flow. The gas supply pipes 232a to 232g are made of, for example, a metal material such as SUS.

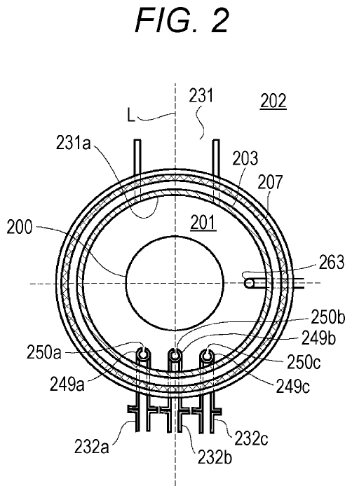

As illustrated in FIG. 2, the nozzles 249a to 249c are provided so as to rise upward in the arrangement direction of the wafer 200 from the lower portion to the upper portion of the inner wall of the reaction tube 203 in an annular space between the inner wall of the reaction tube 203 and the wafer 200, when seen in a plan view. That is, the nozzles 249a to 249c are provided along the wafer arrangement area in the area horizontally surrounding the wafer arrangement area at the side of the wafer arrangement area where the wafer 200 is arranged. When seen in a plan view, the nozzle 249b is disposed to face an exhaust port 231a, which will be described below, in a straight line with the center of the wafer 200 loaded into the process chamber 201 interposed therebetween. The nozzles 249a and 249c are disposed such that a straight line L passing through the nozzle 249b and the center of the exhaust port 231a is interposed from both sides along the inner wall of the reaction tube 203 (the outer periphery of the wafer 200). The straight line L is also a straight line passing through the nozzle 249b and the center of the wafer 200. That is, it can be said that the nozzle 249c is provided on the side opposite to the nozzle 249a with the straight line L interposed therebetween. The nozzles 249a and 249c are disposed line-symmetrically with the straight line L as the axis of symmetry. Gas supply holes 250a to 250c configured to supply gas are respectively provided on the side surfaces of the nozzles 249a to 249c. The gas supply holes 250a to 250c are opened so as to face the exhaust port 231a when seen in a plan view, and allow gas to be supplied toward the wafer 200. A plurality of gas supply holes 250a to 250c are provided from the lower portion to the upper portion of the reaction tube 203.

As a precursor gas, for example, a silane-based gas, containing silicon (Si) serving as a main element constituting a film formed on the surface of the wafer 200 is supplied from the gas supply pipe 232a to the process chamber 201 through the MFC 241a, the valve 243a, and the nozzle 249a. As the silane-based gas, a gas containing Si and halogen, that is, a halosilane-based gas can be used. The halogen contains chlorine (Cl), fluorine (F), bromine (Br), iodine (I), and the like. As the halosilane-based gas, for example, a gas containing silicon, carbon (C), and halogen, that is, an organic halosilane-based gas can be used. As the organic halosilane-based gas, for example, a gas containing Si, C, and Cl, that is, an organic chlorosilane-based gas can be used.

As a first nitrogen (N)- and hydrogen (H)-containing gas, for example, an amine-based gas, is supplied from the gas supply pipe 232b to the process chamber 201 through the MFC 241b, the valve 243b, and the nozzle 249b. The amine-based gas further contains C, and the amine-based gas can also be referred to as a C-, N-, and H-containing gas.

As a second N- and H-containing gas, for example, a hydrogen nitride-based gas, is supplied from the gas supply pipe 232c to the process chamber 201 through the MFC 241c, the valve 243c, and the nozzle 249c.

As an oxygen (O)-containing gas, for example, an O- and H-containing gas, is supplied from the gas supply pipe 232d to the process chamber 201 through the MFC 241d, the valve 243d, the gas supply pipe 232b, and the nozzle 249b.

An inert gas is supplied from the gas supply pipes 232e to 232g to the process chamber 201 through the MFC 241e to 241g, the valves 243e to 243g, the gas supply pipes 232a to 232c, and the nozzles 249a to 249c. The inert gas acts as a purge gas, a carrier gas, a diluting gas, and the like.

A precursor gas supply system (silane-based gas supply system) is mainly configured by the gas supply pipe 232a, the MFC 241a, and the valve 243a. A first N- and H-containing gas supply system (amine-based gas supply system) is mainly configured by the gas supply pipe 232b, the MFC 241b, and the valve 243b. A second N- and H-containing gas supply system (hydrogen nitride-based gas supply system) is mainly configured by the gas supply pipe 232c, the MFC 241c, and the valve 243c. An O-containing gas supply system is mainly configured by the gas supply pipe 232d, the MFC 241d, and the valve 243d. An inert gas supply system is mainly configured by the gas supply pipes 232e to 232g, the MFC 241e to 241g, and the valves 243e to 243g.

One or all of the various supply systems described above may be configured as an integrated supply system 248 in which the valves 243a to 243g, the MFC 241a to 241g, or the like are integrated. The integrated supply system 248 is connected to each of the gas supply pipes 232a to 232g and is configured such that an operation of supplying various gases to the gas supply pipes 232a to 232g, that is, an operation of opening and closing the valves 243a to 243g, a flow rate control operation by the MFCs 241a to 241g, or the like, is controlled by a controller 121 to be described below. The integrated supply system 248 is configured as a single-body-type or split-type integrated unit, and is configured to perform attachment and detachment with respect to the gas supply pipes 232a to 232g or the like in units of integration units and to perform maintenance, replacement, expansion, or the like of the integrated supply system 248 in units of integration units.

Under the sidewall of the reaction tube 203, the exhaust port 231a configured to exhaust an atmosphere in the process chamber 201 is provided. As illustrated in FIG. 2, when seen in a plan view, the exhaust port 231a is provided at a position facing the nozzles 249a to 249c (gas supply holes 250a to 250c) with the wafer 200 interposed therebetween. The exhaust port 231a may be provided from the lower portion to the upper portion of the sidewall of the reaction tube 203, that is, along the wafer arrangement area. An exhaust pipe 231 is connected to the exhaust port 231a. A vacuum pump 246 serving as a vacuum exhauster is connected to the exhaust pipe 231 through a pressure sensor 245 serving as a pressure detector (pressure detection section) configured to detect the pressure in the process chamber 201 and an auto pressure controller (APC) valve 244 serving as a pressure regulator (pressure regulation section). The APC valve 244 is configured to perform vacuum exhaust and vacuum exhaust stop in the process chamber 201 by opening and closing the valve while the vacuum pump 246 is operating, and to regulate the pressure in the process chamber 201 by adjusting the degree of valve opening based on pressure information detected by the pressure sensor 245 while the vacuum pump 246 is operating. An exhaust system is mainly configured by the exhaust pipe 231, the APC valve 244, and the pressure sensor 245. The vacuum pump 246 may be included in the exhaust system.

Under the manifold 209, a seal cap 219 is provided serving as a furnace opening lid that is capable of airtightly closing a lower end opening of the manifold 209. The seal cap 219 is made of, for example, a metal material such as SUS and is formed in a disk shape. On the top surface of the seal cap 219, an O-ring 220b is provided serving as a seal member that abuts against the lower end of the manifold 209. Under the seal cap 219, a rotating mechanism 267 configured to rotate a boat 217 to be described below is installed. A rotational shaft 255 of the rotating mechanism 267 passes through the seal cap 219 and is connected to the boat 217. The rotating mechanism 267 is configured to rotate the wafer 200 by rotating the boat 217. The seal cap 219 is configured to be vertically lifted and lowered by a boat elevator 115 serving as a lifting and lowering mechanism installed outside the reaction tube 203. The boat elevator 115 is configured as a transfer device (transfer mechanism) configured to load and unload (transfer) the wafer 200 into and from the process chamber 201 by lifting and lowering the seal cap 219.

Under the manifold 209, a shutter 219s is provided serving as a furnace opening lid that is capable of airtightly closing the lower end opening of the manifold 209 in a state where the boat 217 is unloaded from the process chamber 201 by lowering the seal cap 219. The shutter 219s is made of, for example, a metal material such as SUS and is formed in a disk shape. On the top surface of the shutter 219s, an O-ring 220c is provided serving as a seal member that abuts against the lower end of the manifold 209. The opening and closing operation (the lifting and lowering operation, the rotating operation, or the like) of the shutter 219s is controlled by a shutter opening/closing mechanism 115s.

The boat 217 serving as a substrate support is configured such that a plurality of sheets of wafers 200, for example, 25 to 200 wafers 200, are vertically aligned and supported in a horizontal posture, with their centers aligned with one another, in multiple stages, that is, arranged apart from one another at predetermined intervals. The boat 217 is made of, for example, a heat resistant material such as quartz or SiC. Under the boat 217, a heat insulating plate 218 that is made of, for example, a heat resistant material such as quartz or SiC, is configured to be supported in multiple stages.

A temperature sensor 263 serving as a temperature detector is installed in the reaction tube 203. An amount of current to be supplied to the heater 207 is regulated based on temperature information detected by the temperature sensor 263, such that the temperature in the process chamber 201 has a desired temperature distribution. The temperature sensor 263 is provided along the inner wall of the reaction tube 203.

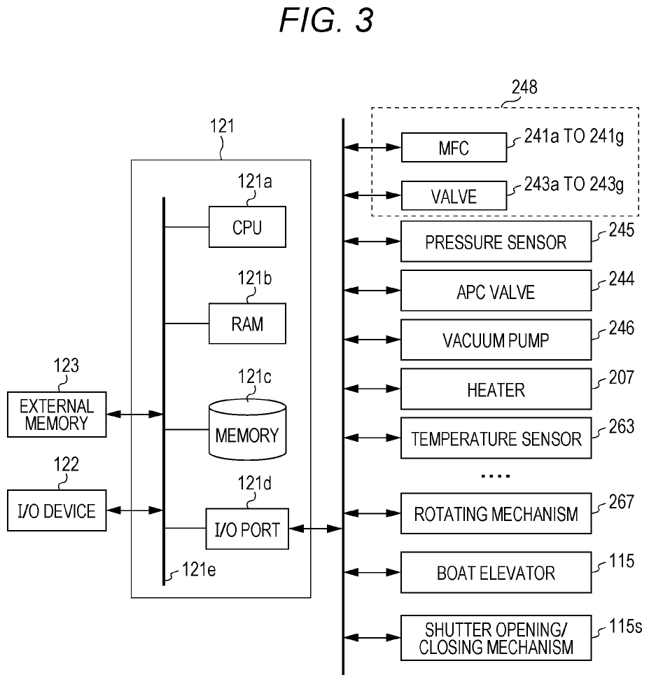

As illustrated in FIG. 3, the controller 121 that is a control section (control device) is configured as a computer that includes a central processing unit (CPU) 121a, a random access memory (RAM) 121b, a memory device 121c, and an input/output (I/O) port 121d. The RAM 121b, the memory device 121c, and the I/O port 121d are configured to exchange data with the CPU 121a through an internal bus 121e. An I/O device 122 that is configured as, for example, a touch panel or the like, is connected to the bus 121e.

The memory device 121c is configured by, for example, a flash memory, a hard disk drive (HDD), a solid state drive (SSD), or the like. In the memory device 121c, a control program for controlling the operation of the substrate processing apparatus or a process recipe including procedures or conditions for substrate processing to be described below is stored to be readable. The process recipe is a combination of various procedures for substrate processing to be described below so as to obtain a desired result when the processes are performed by the controller 121. The process recipe functions as a program. Hereinafter, the process recipe, the control program, and the like will be simply and collectively referred to as a program. In addition, the process recipe is simply referred to as a recipe. When the term “program” is used in the present specification, it may be understood as including the recipe alone, the control program alone, or both the recipe and the control program. The RAM 121b is configured as a memory area (work area) in which programs or data read by the CPU 121a are temporarily retained.

The I/O port 121d is connected to the MFCs 241a to 241g, the valves 243a to 243g, the pressure sensor 245, the APC valve 244, the vacuum pump 246, the temperature sensor 263, the heater 207, the rotating mechanism 267, the boat elevator 115, the shutter opening/closing mechanism 115s, and the like.

The CPU 121a is configured to read the control program from the memory device 121c and execute the read control program and to read the recipe from the memory device 121c in response to an input of an operation command from the I/O device 122, or the like. According to the contents of the read recipe, the CPU 121a is configured to control an operation of controlling the flow rates of various gases by the MFC 241a to 241g, an operation of opening and closing the valves 243a to 243g, an operation of opening and closing the APC valve 244, an operation of regulating the pressure by the APC valve 244 based on the pressure sensor 245, an operation of starting and stopping the vacuum pump 246, an operation of regulating the temperature of the heater 207 based on the temperature sensor 263, an operation of rotating the boat 217 and adjusting the rotation speed of the boat 217 by the rotating mechanism 267, an operation of lifting and lowering the boat 217 by the boat elevator 115, an operation of opening and closing the shutter 219s by the shutter opening/closing mechanism 115s, and the like.

The controller 121 can be configured by installing, on a computer, the above-described program stored in an external memory device 123. The external memory device 123 includes, for example, a magnetic disk such as an HDD, an optical disk such as a CD, a magneto-optical disk such as an MO, a USB memory, or a semiconductor memory such as an SSD, and the like. The memory device 121c or the external memory device 123 is configured as a non-transitory computer-readable recording medium. Hereinafter, the memory device 121c and the external memory device 123 may be simply and collectively referred to as a recording medium. When the term “recording medium” is used in the present specification, it may be understood as including the memory device 121c alone, the external memory device 123 alone, or both the memory device 121c and the external memory device 123. The provision of the program to the computer may be performed by using a communication device such as the Internet or dedicated lines, without using the external memory device 123.

(2) Substrate Processing Process

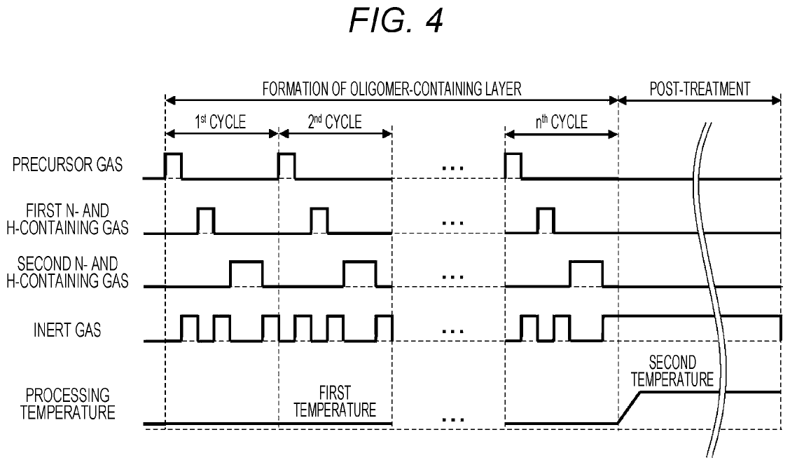

As one of the processes of manufacturing a semiconductor device by using the substrate processing apparatus described above, a processing sequence example of forming a film on the surface of the wafer 200 serving as the substrate will be described mainly with reference to FIG. 4. In the present aspect, an example of using a silicon substrate (silicon wafer) in which a concave portion such as a trench or a hole is formed on the surface of the wafer 200 will be described. In the following description, the operations of the respective elements constituting the substrate processing apparatus are controlled by the controller 121.

As illustrated in FIG. 4, in the processing sequence of the present aspect,

a step of forming an oligomer-containing layer on the surface of the wafer 200 and in the concave portion formed on the surface of the wafer 200 by performing a cycle a predetermined number of times (n times, where n is an integer of 1 or more) under a first temperature, the cycle including a step of supplying a precursor gas to the wafer 200 (supply of precursor gas), a step of supplying a first N- and H-containing gas to the wafer 200 (supply of first N- and H-containing gas), and a step of supplying a second N- and H-containing gas to the wafer 200 (supply of second N- and H-containing gas), so that an oligomer or oligomers (hereinafter simply referred to as oligomer) including an element contained in at least one selected from the group of the precursor gas, the first N- and H-containing gas, and the second N- and H-containing gas is generated, grown, and flowed on the surface of the wafer 200 and in the concave portion; and

a step of forming a film so as to fill the inside of the concave portion by performing a post-treatment (hereinafter referred to as PT) to the wafer 200, which has the oligomer-containing layer formed on the surface of the wafer 200 and in the concave portion, under a second temperature not less than the first temperature, so that the oligomer-containing layer formed on the surface of the wafer 200 and in the concave portion is modified to form the film are performed.

In the processing sequence illustrated in FIG. 4, the supply of the precursor gas, the supply of the first N- and H-containing gas, and the supply of the second N- and H-containing gas are performed non-simultaneously.

In the present specification, for convenience, the processing sequence described above may be represented as follows. The same notation is used in the description of modified examples including the following second and third aspects and the like.

(Precursor gas→first N- and H-containing gas→second N- and H-containing gas)×n→PT

When the term “wafer” is used in the present specification, it may be understood as a wafer itself, or a laminate of a wafer and a predetermined layer or film formed on a surface thereof. When the term “a surface of a wafer” is used in the present specification, it may be understood as a surface of a wafer itself or a surface of a predetermined layer or the like formed on a wafer. When the expression “a predetermined layer is formed on a wafer” is used in the present specification, it may be understood to mean that “a predetermined layer is directly formed on a surface of a wafer itself” or mean that “a predetermined layer is formed on a layer or the like formed on a wafer”. The case in which the term “substrate” is used in the present specification is synonymous with the case in which the term “wafer” is used.

(Wafer Charge and Boat Load)

After the plurality of sheets of wafers 200 are charged into the boat 217 (wafer charge), the shutter 219s is moved by the shutter opening/closing mechanism 115s and the lower end opening of the manifold 209 is opened (shutter open). After that, as illustrated in FIG. 1, the boat 217 that supports the plurality of sheets of wafers 200 is lifted by the boat elevator 115 and is loaded into the process chamber 201 (boat load). In this state, the seal cap 219 is in a state of sealing the lower end of the manifold 209 through the O-ring 220b.

(Pressure Regulation and Temperature Regulation)

After the boat load is completed, the inside of the process chamber 201, that is, the space where the wafer 200 is present, is vacuum-exhausted (exhausted under reduced pressure) by the vacuum pump 246 so as to have a desired pressure (degree of vacuum). In this case, the pressure in the process chamber 201 is measured by the pressure sensor 245, and the APC valve 244 is feedback-controlled based on information about the measured pressure (pressure regulation). In addition, the wafer 200 in the process chamber 201 is heated by the heater 207 until the wafer 200 has a desired processing temperature. In this case, an amount of current supplied to the heater 207 is feedback-controlled based on the temperature information detected by the temperature sensor 263, such that the inside of the process chamber 201 has a desired temperature distribution (temperature regulation). In addition, the rotation of the wafer 200 by the rotating mechanism 267 is started. The exhaust in the process chamber 201 and the heating and rotation of the wafer 200 are all continuously performed at least until the processing of the wafer 200 is completed.

(Formation of Oligomer-Containing Layer)

After that, the following steps 1 to 3 are sequentially performed.

[Step 1]

In this step, a precursor gas is supplied to the wafer 200 in the process chamber 201.

Specifically, the valve 243a is opened so that the precursor gas flows into the gas supply pipe 232a. The precursor gas, the flow rate of which is controlled by the MFC 241a, is supplied to the process chamber 201 through the nozzle 249a and is exhausted from the exhaust port 231a. At this time, the precursor gas is supplied to the wafer 200 (supply of precursor gas). In this case, the valves 243e to 243g may be opened so that an inert gas is supplied to the process chamber 201 through each of the nozzles 249a to 249c.

After a predetermined time has elapsed, the valve 243a is closed and the supply of the precursor gas to the process chamber 201 is stopped. Therefore, the inside of the process chamber 201 is vacuum-exhausted, and the gas and the like remaining in the process chamber 201 are removed from the inside of the process chamber 201. At this time, the valves 243e to 243g are opened and the inert gas is supplied to the process chamber 201 through the nozzles 249a to 249c. The inert gas supplied from the nozzles 249a to 249c acts as a purge gas, whereby the space where the wafer 200 is present, that is, the inside of the process chamber 201 is purged (purge).

As the precursor gas, a C- and halogen-free silane-based gas such as monosilane (SiH₄, abbreviated as MS) gas and disilane (Si₂H₆, abbreviated as DS) gas, a C-free halosilane-based gas such as dichlorosilane (SiH₂Cl₂, abbreviation: DCS) gas and hexachlorodisilane (Si₂Cl₆, abbreviated as HCDS) gas, an alkylsilane-based gas such as trimethylsilane (SiH(CH₃)₃, abbreviated as TMS) gas, dimethylsilane (SiH₂(CH₃)₂, abbreviated as DMS) gas, triethylsilane (SiH(C₂H₅)₃, abbreviated as TES) gas, and diethylsilane (SiH₂(C₂H₅)₂, abbreviated as DES) gas, an alkylene halosilane-based gas such as bis(trichlorosilyl)methane ((SiCl₃)₂CH₂, abbreviated as BTCSM) gas and 1,2-bis(trichlorosilyl) ethane ((SiCl₃)₂C₂H₄, abbreviated as BTCSE) gas, or an alkylhalosilane-based gas such as trimethylchlorosilane (SiCl(CH₃)₃, abbreviated as TMCS) gas, dimethyldichlorosilane (SiCl₂(CH₃)₂, abbreviated as DMDCS) gas, triethylchlorosilane (SiCl(C₂H₅)₃, abbreviated as TECS) gas, diethyldichlorosilane (SiCl₂(C₂H₅)₂, abbreviated as DEDCS) gas, 1,1,2,2-tetrachloro-1,2-dimethyldisilane ((CH₃)₂Si₂Cl₄, abbreviated as TCDMDS) gas, and 1,2-dichloro-1,1, 2,2-tetramethyldisilane ((CH₃)₄Si₂Cl₂, abbreviated as DCTMDS) gas can be used.

As the inert gas, a rare gas such as nitrogen (N₂) gas, argon (Ar) gas, helium (He) gas, neon (Ne) gas, and xenon (Xe) gas can be used. This point is also the same for each step to be described below.

[Step 2]

In this step, a first N- and H-containing gas is supplied to the wafer 200 in the process chamber 201.

Specifically, the valve 243b is opened so that the first N- and H-containing gas flows into the gas supply pipe 232b. The first N- and H-containing gas, the flow rate of which is controlled by the MFC 241b, is supplied to the process chamber 201 through the nozzle 249b and is exhausted from the exhaust port 231a. At this time, the first N- and H-containing gas is supplied to the wafer 200 (supply of first N- and H-containing gas). In this case, the valves 243e to 243g may be opened so that an inert gas is supplied to the process chamber 201 through each of the nozzles 249a to 249c.

After a predetermined time has elapsed, the valve 243b is closed and the supply of the first N- and H-containing gas to the process chamber 201 is stopped. Therefore, the gas and the like remaining in the process chamber 201 are removed from the process chamber 201, depending on the same processing procedure and processing conditions as in the purge in step 1.

As the first N- and H-containing gas, for example, a hydrogen nitride-based gas such as ammonia (NH₃) gas, an ethylamine-based gas such as monoethylamine (C₂H₅NH₂, abbreviated as MEA) gas, diethylamine ((C₂H₅)₂NH, abbreviated as DEA) gas, and triethylamine ((C₂H₅)₃N, abbreviated as TEA) gas, a methylamine-based gas such as monomethylamine (CH₃NH₂, abbreviated as MMA) gas, dimethylamine ((CH₃)₂NH, abbreviated as DMA) gas, and trimethylamine ((CH₃)₃N, abbreviated as TMA) gas, an organic hydrazine-based gas such as monomethylhydrazine ((CH₃)HN₂H₂, abbreviated as MMH) gas, dimethylhydrazine ((CH₃)₂N₂H₂, abbreviated as DMH) gas, and trimethylhydrazine ((CH₃)₂N₂(CH₃)H, abbreviated as TMH) gas, or a cyclic amine-based gas such as pyridine (C₅H₅N) gas and piperazine (C₄H₁₀N₂) gas can be used.

[Step 3]

In this step, a second N- and H-containing gas is supplied to the wafer 200 in the process chamber 201.

Specifically, the valve 243c is opened so that the second N- and H-containing gas flows into the gas supply pipe 232c. The second N- and H-containing gas, the flow rate of which is controlled by the MFC 241c, is supplied to the process chamber 201 through the nozzle 249c and is exhausted from the exhaust port 231a. At this time, the second N- and H-containing gas is supplied to the wafer 200 (supply of second N- and H-containing gas). In this case, the valves 243e to 243g may be opened so that an inert gas is supplied to the process chamber 201 through each of the nozzles 249a to 249c.

After a predetermined time has elapsed, the valve 243c is closed and the supply of the second N- and H-containing gas to the process chamber 201 is stopped. Therefore, the gas and the like remaining in the process chamber 201 are removed from the process chamber 201, depending on the same processing procedure and processing conditions as in the purge in step 1.

As the second N- and H-containing gas, for example, a hydrogen nitride-based gas such as ammonia (NH₃) gas, diazene (N₂H₂) gas, hydrazine (N₂H₄) gas, and N₃H₈ gas can be used. As the second N- and H-containing gas, a gas having a molecular structure different from that of the first N- and H-containing gas may be preferably used. However, as the second N- and H-containing gas, a gas having the same molecular structure as that of the first N- and H-containing gas can also be used, depending on the processing conditions.

[Performing Predetermined Number of Times]

After that, steps 1 to 3 described above are performed non-simultaneously, that is, cycles without synchronization are performed a predetermined number of times (n times, where n is an integer of 1 or more).

At this time, the cycle is performed a predetermined number of times under the condition (temperature) in which the physical adsorption of the precursor gas occurs dominantly rather than the chemical adsorption of the precursor gas when the precursor gas is present alone. Preferably, the cycle is performed a predetermined number of times under the condition (temperature) in which the physical adsorption of the precursor gas occurs dominantly rather than the thermal decomposition of the precursor gas and the chemical adsorption of the precursor gas when the precursor gas is present alone. In addition, preferably, the cycle is performed a predetermined number of times under the condition (temperature) in which the physical adsorption of the precursor gas occurs dominantly rather than the chemical adsorption of the precursor gas without thermal decomposition of the precursor gas when the precursor gas is present alone. In addition, preferably, the cycle is performed a predetermined number of times under the condition (temperature) that causes fluidity in the oligomer-containing layer. Furthermore, preferably, the cycle is performed a predetermined number of times under the condition (temperature) in which that the oligomer-containing layer flows into the concave portion formed on the surface of the wafer 200 and the inside of the concave portion is filled with the oligomer-containing layer from a bottom of the inside of the concave portion.

For example, the processing conditions for the supply of the precursor gas are as follows:

precursor gas supply flow rate: 10 to 1,000 sccm,

precursor gas supply time: 1 to 300 seconds,

inert gas supply flow rate (for each gas supply pipe): 10 to 10,000 sccm,

processing temperature (first temperature): 0 to 150° C., preferably 10 to 100° C., and more preferably 20 to 60° C., and

processing pressure: 10 to 6,000 Pa, and preferably 50 to 2,000 Pa.

In the present specification, the notation of the numerical range such as “0 to 150° C.” means that a lower limit value and an upper limit value are included in the range. Therefore, for example, “0 to 150° C.” means “0° C. or more and 150° C. or less”. The same applies to other numerical ranges.

For example, the processing conditions for the supply of the first N- and H-containing gas are as follows:

first N- and H-containing gas supply flow rate: 10 to 5,000 sccm, and

first N- and H-containing gas supply time: 1 to 300 seconds.

Other processing conditions can be the same as the processing conditions for the supply of the precursor gas.

For example, the processing conditions for the supply of the second N- and H-containing gas are as follows:

second N- and H-containing gas supply flow rate: 10 to 5,000 sccm, and

second N- and H-containing gas supply time: 1 to 300 seconds.

Other processing conditions can be the same as the processing conditions in the supply of the precursor gas.

By performing the supply of the precursor gas, the supply of the first N- and H-containing gas, and the supply of the second N- and H-containing gas under the processing conditions described above, oligomer including elements contained in at least one selected from the group of the precursor gas, the first N- and H-containing gas, and the second N- and H-containing gas is generated on the concave portion and the surface of the wafer 200, is grown, and is flowed, so that the oligomer-containing layer can be formed on the surface of the wafer 200 and in the concave portion. The oligomer refers to a polymer having a relatively low molecular weight (for example, a molecular weight of 10,000 or less) to which a relatively small amount (for example, 10 to 100) of monomers is bonded. In a case where an alkylhalosilane-based gas such as an alkylchlorosilane-based gas, an amine-based gas, and a hydrogen nitride-based gas are respectively used as the precursor gas, the first N- and H-containing gas, and the second N- and H-containing gas, the oligomer-containing layer is, for example, a layer containing various elements, such as Si, Cl, and N, and a material represented by the chemical formula of CₓH₂ₓ₊₁ (where x is an integer of 1 to 3), such as CH₃ and C₂H₅.

When the processing temperature described above is set to less than 0° C., the precursor gas supplied to the process chamber 201 is easily liquefied. Therefore, it may be difficult to supply the precursor gas to the wafer 200 in a gaseous state. In this case, the reaction for forming the oligomer-containing layer described above may be difficult to proceed, and it may be difficult to form the oligomer-containing layer on the surface of the wafer 200 and in the concave portion. This problem can be solved by setting the processing temperature to 0° C. or more. This problem can be solved sufficiently by setting the processing temperature to 10° C. or more, and this problem can be solved more sufficiently by setting the processing temperature to 20° C. or more.

In addition, when the processing temperature is set to more than 150° C., the catalytic action of the first N- and H-containing gas to be described below is weakened. Therefore, the reaction for forming the oligomer-containing layer described above may be difficult to proceed. In this case, the desorption of the oligomer generated on the surface of the wafer 200 and in the concave portion is dominant rather than the grown of the oligomer. Therefore, it may be difficult to form the oligomer-containing layer on the surface of the wafer 200 and in the concave portion. This problem can be solved by setting the processing temperature to 150° C. or less. This problem can be solved sufficiently by setting the processing temperature to 100° C. or less, and this problem can be solved more sufficiently by setting the processing temperature to 60° C. or less.

Due to this, the processing temperature is 0° C. or more and 150° C. or less, preferably 10° C. or more and 100° C. or less, and more preferably 20° C. or more and 60° C. or less.

For example, the processing conditions for the purge are as follows:

inert gas supply flow rate (for each gas supply pipe): 10 to 20,000 sccm,

inert gas supply time: 1 to 300 seconds, and

processing pressure: 10 to 6,000 Pa.

Other processing conditions can be the same as the processing conditions for the supply of the precursor gas.

By performing the purge under the processing conditions described above, it is possible to discharge surplus components included in the oligomer-containing layer, for example, surplus gas or by-products containing Cl. while promoting the flow of the oligomer-containing layer formed on the surface of the wafer 200 and in the concave portion.

(Post-Treatment)

After the oligomer-containing layer is formed on the surface of the wafer 200 and in the concave portion, the output of the heater 207 is adjusted so as to change the temperature of the wafer 200 to a second temperature equal to or higher than the first temperature described above, preferably to a second temperature higher than the first temperature described above.

At this time, an inert gas such as N₂ gas as an N-containing gas is supplied to the wafer 200 in the process chamber 201. Specifically, the valves 243e to 243g are opened so that the inert gas flow into the gas supply pipes 232e to 232g. The inert gas, the flow rate of which is controlled by the MFCs 241e to 241g, is supplied to the process chamber 201 through the nozzles 249a to 249c and is exhausted from the exhaust port 231a. At this time, the inert gas is supplied to the wafer 200.

This step is preferably performed under the condition that causes fluidity in the oligomer-containing layer formed on the surface of the wafer 200 and in the concave portion. In addition, this step is preferably performed under the condition that densifies the oligomer-containing layer by discharging surplus components included in the oligomer-containing layer, for example, surplus gas or by-products containing Cl while promoting the flow of the oligomer-containing layer formed on the surface of the wafer 200 and in the concave portion.

For example, the processing conditions for the post-treatment are as follows:

inert gas supply flow rate (for each gas supply pipe): 10 to 20,000 sccm,

processing temperature (second temperature): 100 to 1,000° C., and preferably 200 to 600° C.,

processing pressure: 10 to 80,000 Pa, and preferably 200 to 6,000 Pa, and

processing time: 300 to 10,800 seconds.

By performing the post-treatment under the conditions described above, the oligomer-containing layer formed on the surface of the wafer 200 and in the concave portion can be modified. This makes it possible to form a silicon carbonitride film (SiCN film) containing Si, C, and N as a film formed by modifying the oligomer-containing layer so as to fill the inside of the concave portion. In addition, surplus components included in the oligomer-containing layer are discharged while promoting the flow of the oligomer-containing layer, and the oligomer-containing layer can be densified.

(After-Purge and Atmospheric Pressure Return)

After the formation of the SiCN film is completed, an inert gas serving as a purge gas is supplied from each of the nozzles 249a to 249c to the process chamber 201 and is exhausted from the exhaust port 231a. Due to this, the inside of the process chamber 201 is purged, and the gases or reaction by-products remaining in the process chamber 201 are removed from the inside of the process chamber 201 (after-purge). After that, the atmosphere in the process chamber 201 is replaced with an inert gas (replacement of inert gas), and the pressure in the process chamber 201 is returned to the normal pressure (atmospheric pressure return).

(Boat Unload and Wafer Discharge)

After that, the seal cap 219 is lowered by the boat elevator 115 and the lower end of the manifold 209 is opened. The processed wafer 200 is unloaded from the lower end of the manifold 209 to the outside of the reaction tube 203 in a state in which the processed wafer 200 is supported to the boat 217 (boat unload). After the boat unload, the shutter 219s is moved and the lower end opening of the manifold 209 is sealed through the O-ring 220c by the shutter 219s (shutter close). After the processed wafer 200 is unloaded to the outside of the reaction tube 203, the processed wafer 200 is discharged from the boat 217 (wafer discharge).

(3) Effect of the Present Aspect

According to the present aspect, one or more effects shown below can be obtained.

(a) By performing the formation of the oligomer-containing layer under the first temperature described above and performing the post-treatment under the second temperature equal to or higher than the first temperature, it is possible to improve the filling characteristics of the film formed in the concave portion. By performing the post-treatment under the second temperature higher than the first temperature, the effects described above can be further enhanced.

(b) In the formation of the oligomer-containing layer, the cycle is performed a predetermined number of times under the conditions in which the physical adsorption of the precursor gas occurs dominantly rather than the chemical adsorption of the precursor gas when the precursor gas is present alone, and thus, it is possible to increase the fluidity of the oligomer-containing layer and to improve the filling characteristics of the film formed in the concave portion.

(c) In the formation of the oligomer-containing layer, the cycle is performed a predetermined number of times under the conditions in which the physical adsorption of the precursor gas occurs dominantly rather than the thermal decomposition of the precursor gas and the chemical adsorption of the precursor gas when the precursor gas is present alone, and thus, it is possible to increase the fluidity of the oligomer-containing layer. As a result, it is possible to improve the filling characteristics of the film formed in the concave portion.

(d) In the formation of the oligomer-containing layer, the cycle is performed a predetermined number of times under the conditions in which the physical adsorption of the precursor gas occurs dominantly rather than the chemical adsorption of the precursor gas without the thermal decomposition of the precursor gas when the precursor gas is present alone, and thus, it is possible to increase the fluidity of the oligomer-containing layer. As a result, it is possible to improve the filling characteristics of the film formed in the concave portion.

(e) In the formation of the oligomer-containing layer, the cycle is performed a predetermined number of times under the conditions that cause the fluidity in the oligomer-containing layer, and thus, it is possible to improve the filling characteristics of the film formed in the concave portion.

(f) In the formation of the oligomer-containing layer, the cycle is performed a predetermined number of times under the conditions in which the oligomer-containing layer flows into the concave portion and the inside of the concave portion is filled with the oligomer-containing layer from a bottom of the inside of the concave portion, and thus, it is possible to improve the filling characteristics of the film formed in the concave portion.

(g) Si, C, and Cl can be contained in the oligomer-containing layer by using the alkylchlorosilane-based gas as the precursor gas.

(h) By making the molecular structure of the first N- and H-containing gas different from the molecular structure of the second N- and H-containing gas, different roles can be given to the respective gases. For example, as in the present aspect, the amine-based gas is used as the first N- and H-containing gas and acts as a catalyst. By supplying the precursor gas, the precursor gas physically adsorbed on the surface of the wafer 200 can be activated. In addition, the hydrogen nitride-based gas is used as the second N- and H-containing gas and acts as an N source. Therefore, N can be contained in the oligomer-containing layer.

(i) In the formation of the oligomer-containing layer, the cycle of supplying the precursor gas, supplying the first N- and H-containing gas, and supplying the second N- and H-containing gas is non-simultaneously performed a predetermined number of times, and thus, it is possible to improve the filling characteristics of the film formed in the concave portion.

It is considered that, by separately supplying the precursor gas and the first N- and H-containing gas acting as the catalyst at different timings, it is possible to control the variation in the mixing condition between the precursor gas and the first N- and H-containing gas. According to the present aspect, the variation in growth in fine regions is improved by improving the variation in growth of each oligomer generated at a plurality of locations on the surface of the wafer 200 and in the concave portion, and thus, it is possible to suppress the generation of voids or seams in the concave portion. As a result, it is possible to improve the filling characteristics of the film formed in the concave portion. That is, void-free and seamless filling is possible.

(j) In the formation of the oligomer-containing layer, the purge is performed at a predetermined timing, and thus, it is possible to improve the filling characteristics of the film formed in the concave portion. In addition, it is possible to reduce the impurity concentration of the film formed so as to fill the inside of the concave portion. This makes it possible to improve the wet etching resistance of the film formed in the concave portion.

(k) The post-treatment is performed under the conditions that cause the fluidity in the oligomer-containing layer, and thus, it is possible to improve the filling characteristics of the film formed in the concave portion.

(l) In the post-treatment, the filling characteristics of the film formed in the concave portion can be improved by discharging surplus components included in the oligomer-containing layer to densify the oligomer-containing layer, while promoting the flow of the oligomer-containing layer. In addition, it is possible to reduce the impurity concentration of the film formed so as to fill the concave portion. Furthermore, it is possible to increase the film density. This makes it possible to improve the wet etching resistance of the film formed in the concave portion.

(m) In the post-treatment, the flow of the oligomer-containing layer is promoted by supplying the N-containing gas to the wafer 200. Therefore, it is possible to improve the filling characteristics of the film formed in the concave portion. In addition, it is possible to reduce the impurity concentration of the film formed so as to fill the concave portion. Furthermore, it is possible to increase the film density. This makes it possible to improve the wet etching resistance of the film formed in the concave portion.

(n) The effects described above can be obtained in the same manner even when the above-described various precursor gases, the above-described various first N- and H-containing gases, the above-described various second N- and H-containing gases, and the above-described various inert gases are used to form the oligomer-containing layer. In addition, the effects described above can be obtained in the same manner even when the gas supply order in the cycle is changed. Furthermore, the effects described above can be obtained in the same manner even when gases other than the N-containing gas are used in the post-treatment.

<Second Aspect of the Present Disclosure>

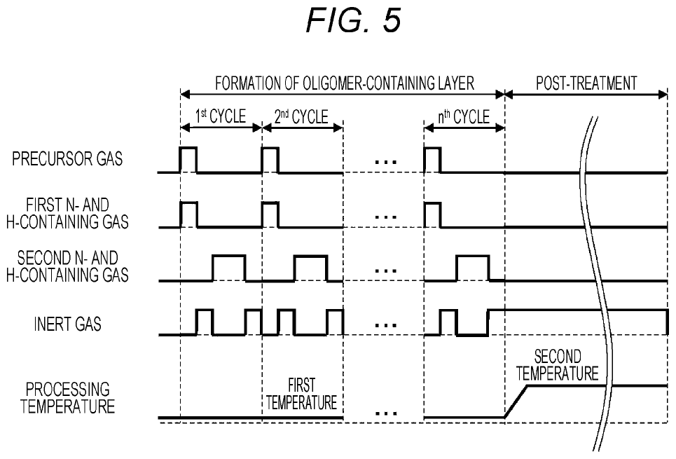

Next, the second aspect of the present disclosure will be described mainly with reference to FIG. 5.

As in the processing sequence illustrated in FIG. 5 or below, in the formation of the oligomer-containing layer, a cycle may be performed a predetermined number of times (n times, where n is an integer of 1 or more), the cycle including non-simultaneously performing:

a step of simultaneously performing a supplying the precursor gas to the wafer 200 and supplying the first N- and H-containing gas to the wafer 200; and

a step of supplying the second N- and H-containing gas to the wafer 200.

(Precursor gas→first N- and H-containing gas→second N- and H-containing gas)×n→PT

The present aspect also has the same effects as those of the first aspect described above. In addition, in the present aspect, since the precursor gas and the first N- and H-containing gas are simultaneously supplied, it is possible to improve the cycle rate and increase the productivity of the substrate processing.

<Third Aspect of the Present Disclosure>

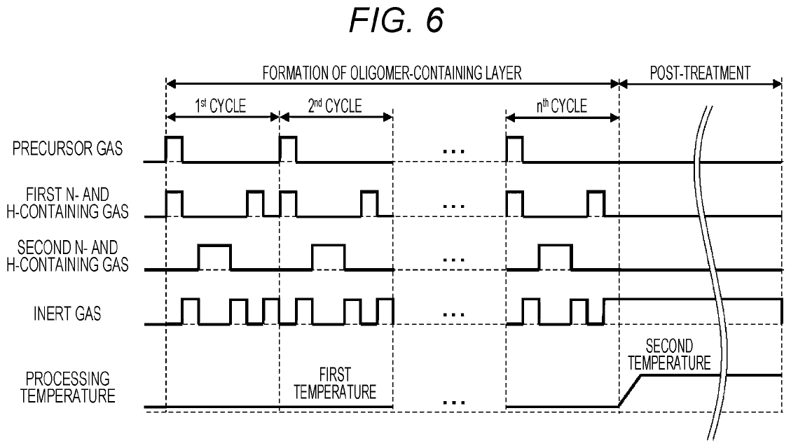

Next, the third aspect of the present disclosure will be described mainly with reference to FIG. 6.

As in the processing sequence illustrated in FIG. 6 or below, in the formation of the oligomer-containing layer, a cycle may be performed a predetermined number of times (n times, where n is an integer of 1 or more), the cycle including non-simultaneously performing:

a step of simultaneously performing supplying the precursor gas to the wafer 200 and supplying the first N- and H-containing gas to the wafer 200;

a step of supplying the second N- and H-containing gas to the wafer 200; and

a step of supplying the first N- and H-containing gas to the wafer 200.

(Precursor gas→first N- and H-containing gas→second N- and H-containing gas→first N- and H-containing gas)×n→PT

The present aspect also has the same effects as those of the first aspect described above. In the present aspect, since the first N- and H-containing gas that flows for the first time in the cycle acts as a catalyst, the precursor gas can be activated. In addition, the first N- and H-containing gas that flows for the second time in the cycle can act as a gas for removing by-products generated during the formation of the oligomer-containing layer, that is, a reactive purge gas. The processing conditions for supplying these first N- and H-containing gases can be the same as the processing conditions for supplying the first N- and H-containing gas described above.

<Other Aspects of the Present Disclosure>

Various aspects of the present disclosure have been concretely described above. However, the present disclosure is not limited to the above-described aspects, and various changes can be made thereto without departing from the gist thereof.

For example, in the post-treatment, an H-containing gas such as hydrogen (H₂) gas may be supplied to the wafer 200 on which the oligomer-containing layer is formed. An N-containing gas such as NH₃ gas, that is, an N- and H-containing gas may be supplied to the wafer 200. An O-containing gas such as H₂O gas, that is, an O- and H-containing gas may be supplied to the wafer. O₂ gas may be supplied as the O-containing gas. That is, in the post-treatment, at least one selected from the group of the N-containing gas, the H-containing gas, the N- and H-containing gas, the O-containing gas, and the O- and H-containing gas may be supplied to the wafer 200 on which the oligomer-containing layer is formed.

For example, the processing conditions when the H-containing gas is supplied in the post-treatment are as follows:

H-containing gas supply flow rate: 10 to 3,000 sccm,

processing temperature (second temperature): 100 to 1,000° C., and preferably 200 to 600° C.,

processing pressure: 10 to 1,000 Pa, and preferably 200 to 800 Pa, and

processing time: 300 to 10,800 seconds.

For example, the processing conditions when the N- and H-containing gas is supplied in the post-treatment are as follows:

N- and H-containing gas supply flow rate: 10 to 10,000 sccm,

processing temperature (second temperature): 100 to 1,000° C., and preferably 200 to 600° C.,

processing pressure: 10 to 6,000 Pa, and preferably 200 to 2,000 Pa, and

processing time: 300 to 10,800 seconds.

For example, the processing conditions when the O-containing gas is supplied in the post-treatment are as follows:

O-containing gas supply flow rate: 10 to 10,000 sccm,

processing temperature (second temperature): 100 to 1,000° C., and preferably 100 to 600° C.,

processing pressure: 10 to 90,000 Pa, and preferably 20,000 to 80,000 Pa, and

processing time: 300 to 10,800 seconds.

The present aspect also has the same effects as those of the first aspect described above.

In a case where the post-treatment is performed in an H-containing gas atmosphere, or in a case where the post-treatment is performed in an N- and H-containing gas atmosphere, it is possible to increase the fluidity of the oligomer-containing layer and to improve the filling characteristics of the film formed in the concave portion, compared to a case where the post-treatment is performed in an inert gas atmosphere such as N₂ gas. In addition, in a case where the post-treatment is performed in an H-containing gas atmosphere, or in a case where the post-treatment is performed in an N- and H-containing gas atmosphere, it is possible to reduce the impurity concentration of the film formed in the concave portions, to increase the film density, and to improve the wet etching resistance, compared to a case where the post-treatment is performed in an inert gas atmosphere such as N₂ gas. In a case where the post-treatment is performed in an N- and H-containing gas atmosphere, it is possible to enhance these effects, compared to a case where the post-treatment is performed in an H-containing gas atmosphere.

In a case where the post-treatment is performed in an O-containing gas atmosphere, O can be contained in a film formed by modifying the oligomer-containing layer. This film can be a silicon oxycarbonitride film (SiOCN film) that is a film containing Si, O, C, and N.

In addition, for example, in the post-treatment,

a step of supplying at least one selected from the group of an N-containing gas such as N₂ gas, an H-containing gas such as H₂ gas, and an N- and H-containing gas such as NH₃ gas to the wafer 200 on which the oligomer-containing layer is formed and

a step of supplying an O-containing gas (O- and H-containing gas) such as H₂O gas to the wafer 200 on which the oligomer-containing layer is formed

may be performed non-simultaneously. In this case, of the two steps, the former step can be referred to as a first post-treatment, and the latter step can be referred to as a second post-treatment.

The processing conditions for each of the first and second post-treatments can be the same as the processing conditions for the post-treatment of each aspect described above.

Even in this case, the same effects as those of the first aspect described above can be obtained.

In a case where the post-treatment is performed in an O-containing gas atmosphere, O can be contained in a film formed by modifying the oligomer-containing layer. This film can be an SiOCN film. In addition, by using the O- and H-containing gas such as H₂O gas, which has a relatively low oxidizing power, as the O-containing gas, it is possible to suppress the desorption of C from the SiOCN film formed by modifying the oligomer-containing layer. In addition, by performing the first and second post-treatments in this order, it is possible to suppress the desorption of C from the SiOCN film formed by modifying the oligomer-containing layer.

In addition, for example, as in the processing sequence shown below, the first aspect and a part of the third aspect may be combined.

(Precursor gas→first N- and H-containing gas→second N- and H-containing gas→first N- and H-containing gas)×n→PT

That is, in the formation of the oligomer-containing layer, a cycle may be non-simultaneously performed a predetermined number of times (n times, where n is an integer of 1 or more), the cycle including:

a step of supplying the precursor gas to the wafer 200;

a step of supplying the first N- and H-containing gas to the wafer 200;

a step of supplying the second N- and H-containing gas to the wafer 200; and

a step of supplying the first N- and H-containing gas to the wafer 200.

According to this processing sequence, it is possible to obtain both the effect obtained by the first aspect and the effect obtained by a part of the third aspect.

In the aspect described above, an example in which the formation of the oligomer-containing layer and the post-treatment are performed in the same process chamber 201 (in-situ) has been described. However, the present disclosure is not limited to such an aspect. For example, the formation of the oligomer-containing layer and the post-treatment may be performed in separate process chambers (ex-situ). Even in this case, the same effects as the effects in the aspect described above can be obtained. In the various cases described above, when these steps are performed in-situ, such processing can be performed consistently while the wafer 200 is kept under vacuum, without exposing the wafer 200 to the atmosphere on the way, and stable substrate processing can be performed. In addition, when these steps are performed ex-situ, a temperature in each process chamber can be preset to, for example, a processing temperature at each step or a temperature close thereto, and the time required for temperature regulation can be reduced, thereby improving production efficiency.

So far, examples of forming the SiCN film or the SiOCN film so as to fill the concave portion formed on the surface of the wafer 200 have been described, but the present disclosure is not limited to these examples. That is, the present disclosure is also suitably applicable to the case of forming a silicon nitride film (SiN film), a silicon oxide film (SiO film), a silicon oxycarbide film (SiOC film), and a silicon film (Si film) by arbitrarily combining gas types of the precursor gas, the first N- and H-containing gas, and the second N- and H-containing gas so as to fill the inside of the concave portion formed on the surface of the wafer 200. Even in this case, the same effects as the effects in the aspect described above can be obtained.

It is preferable that the recipe used in the substrate processing is individually prepared according to the contents of the processing and is stored in the memory device 121c through the telecommunication line or the external memory device 123. It is preferable that, when the processing is started, the CPU 121a appropriately selects a suitable recipe from a plurality of recipes stored in the memory device 121c according to the contents of the processing. Therefore, films having various film types, composition ratios, film qualities, and film thicknesses can be formed with good reproducibility by using a single substrate processing apparatus. In addition, since the workload of an operator can be reduced, the processing can be promptly started while avoiding operation mistakes.

The recipe described above is not limited to the case of newly creating a recipe. For example, the recipe may be prepared by modifying an existing recipe having already been installed on the substrate processing apparatus. When the recipe is modified, the modified recipe may be installed on the substrate processing apparatus through the telecommunication line or the recording medium storing the corresponding recipe. In addition, the existing recipe having already been installed on the substrate processing apparatus may be directly modified by operating the I/O device 122 provided in the existing substrate processing apparatus.

In the aspects described above, an example of forming a film by using a batch type substrate processing apparatus that processes a plurality of substrates at once has been described. The present disclosure is not limited to the aspects described above. For example, the present disclosure can also be suitably applied to a case where a film is formed by using a single-wafer type substrate processing apparatus that processes one or several substrates at once. Furthermore, in the aspects described above, an example of forming a film by using a substrate processing apparatus having a hot wall type process furnace has been described. The present disclosure is not limited to the aspects described above, and can be suitably applied to a case where a film is formed by using a substrate processing apparatus having a cold wall type process furnace.

Even when these substrate processing apparatuses are used, the film formation can be performed under the same sequence and processing conditions as the above-described aspects and modified examples, and the same effects as the above-described aspects and modified examples can be obtained.

Furthermore, the above-described aspects and modified examples can be used in combination as appropriate. In this case, the processing procedures and processing conditions can be, for example, the same as the processing procedures and processing conditions of the aspects described above.

According to the present disclosure, it is possible to improve the characteristics of the film formed so as to fill the concave portion provided on the surface of the substrate.

What is claimed is:

1. A method of processing a substrate, comprising:
(a) forming an oligomer-containing layer on a surface of a substrate and in a concave portion formed on the surface of the substrate by performing a cycle a predetermined number of times under a first temperature, the cycle including supplying a precursor gas to the substrate, supplying a first nitrogen- and hydrogen-containing gas to the substrate, and supplying a second nitrogen- and hydrogen-containing gas to the substrate, so that an oligomer including an element contained in at least one selected from the group of the precursor gas, the first nitrogen- and hydrogen-containing gas, and the second nitrogen- and hydrogen-containing gas is generated, grown, and flowed on the surface of the substrate and in the concave portion; and
(b) forming a film so as to fill the inside of the concave portion by performing a post-treatment to the substrate, which has the oligomer-containing layer formed on the surface of the substrate and in the concave portion, under a second temperature not less than the first temperature, so that the oligomer-containing layer formed on the surface of the substrate and in the concave portion is modified to form the film.

2. The method according to claim 1, wherein, in (a), the cycle is performed a predetermined number of times under a condition in which physical adsorption of the precursor gas occurs dominantly rather than chemical adsorption of the precursor gas when the precursor gas is present alone.

3. The method according to claim 1, wherein, in (a), the cycle is performed a predetermined number of times under a condition in which physical adsorption of the precursor gas occurs dominantly rather than thermal decomposition of the precursor gas and chemical adsorption of the precursor gas when the precursor gas is present alone.

4. The method according to claim 1, wherein, in (a), the cycle is performed a predetermined number of times under a condition in which physical adsorption of the precursor gas occurs dominantly rather than chemical adsorption of the precursor gas without thermal decomposition of the precursor gas when the precursor gas is present alone.

5. The method according to claim 1, wherein, in (a), the cycle is performed a predetermined number of times under a condition that causes fluidity in the oligomer-containing layer.

6. The method according to claim 1, wherein, in (a), the cycle is performed a predetermined number of times under a condition in which the oligomer-containing layer flows into the concave portion and the inside of the concave portion is filled with the oligomer-containing layer from a bottom of the inside of the concave portion.

7. The method according to claim 1, wherein the cycle in (a) comprises non-simultaneously performing:
supplying the precursor gas to the substrate;
supplying the first nitrogen- and hydrogen-containing gas to the substrate; and
supplying the second nitrogen- and hydrogen-containing gas to the substrate.

8. The method according to claim 1, wherein the cycle in (a) comprises non-simultaneously performing:
simultaneously performing supplying the precursor gas to the substrate and supplying the first nitrogen- and hydrogen-containing gas to the substrate; and
supplying the second nitrogen- and hydrogen-containing gas to the substrate.

9. The method according to claim 1, wherein the cycle in (a) comprises non-simultaneously performing:
simultaneously performing supplying the precursor gas to the substrate and supplying the first nitrogen- and hydrogen-containing gas to the substrate;
supplying the second nitrogen- and hydrogen-containing gas to the substrate; and
supplying the first nitrogen- and hydrogen-containing gas to the substrate.

10. The method according to claim 1, wherein the cycle in (a) further comprises purging a space where the substrate is present, and
the purging discharges surplus components contained in the oligomer-containing layer while promoting the flow of the oligomer-containing layer.

11. The method according to claim 1, wherein, in (b), the post-treatment is performed under a condition that causes fluidity in the oligomer-containing layer.

12. The method according to claim 1, wherein, in (b), surplus components contained in the oligomer-containing layer is discharged while promoting the flow of the oligomer-containing layer, and the oligomer-containing layer is densified.

13. The method according to claim 1, wherein the precursor gas contains silicon and halogen.

14. The method according to claim 1, wherein the precursor gas contains silicon, carbon, and halogen.

15. The method according to claim 1, wherein the first nitrogen- and hydrogen-containing gas and the second nitrogen- and hydrogen-containing gas have different molecular structures.

16. The method according to claim 1, wherein the first nitrogen- and hydrogen-containing gas is an amine-based gas, and the second nitrogen- and hydrogen-containing gas is a hydrogen nitride-based gas.

17. The method according to claim 1, wherein, in (b), at least one selected from the group of a nitrogen-containing gas, a hydrogen-containing gas, a nitrogen- and hydrogen-containing gas, and an oxygen-containing gas is supplied to the substrate.

18. The method according to claim 1, wherein (b) comprises:
supplying at least one selected from the group of a nitrogen-containing gas, a hydrogen-containing gas, and a nitrogen- and hydrogen-containing gas to the substrate; and
supplying an oxygen-containing gas to the substrate.

19. A method of manufacturing a semiconductor device comprising the method of claim 1.

20. A substrate processing apparatus comprising:
a process chamber in which a substrate is processed;
a precursor gas supply system configured to supply a precursor gas to the substrate in the process chamber;
a first nitrogen- and hydrogen-containing gas supply system configured to supply a first nitrogen- and hydrogen-containing gas to the substrate in the process chamber;
a second nitrogen- and hydrogen-containing gas supply system configured to supply a second nitrogen- and hydrogen-containing gas to the substrate in the process chamber;
a heater configured to heat the substrate in the process chamber; and
a controller that is capable of controlling the precursor gas supply system, the first nitrogen- and hydrogen-containing gas supply system, the second nitrogen- and hydrogen-containing gas supply system, and the heater so as to perform in the process chamber:
(a) forming an oligomer-containing layer on a surface of a substrate and in a concave portion formed on the substrate by performing a cycle a predetermined number of times under a first temperature, the cycle including supplying the precursor gas to the substrate, supplying the first nitrogen- and hydrogen-containing gas to the substrate, and supplying the second nitrogen- and hydrogen-containing gas to the substrate, so that an oligomer including an element contained in at least one selected from the group of the precursor gas, the first nitrogen- and hydrogen-containing gas, and the second nitrogen- and hydrogen-containing gas is generated, grown, and flowed on the surface of the substrate and in the concave portion; and
(b) forming a film so as to fill the inside of the concave portion by performing a post-treatment to the substrate, which has the oligomer-containing layer formed on the surface of the substrate and in the concave portion, under a second temperature not less than the first temperature, so that the oligomer-containing layer formed on the surface of the substrate and in the concave portion is modified to form the film.

21. A non-transitory computer-readable recording medium storing a program that causes, by a computer, a substrate processing apparatus to perform:
(a) forming an oligomer-containing layer on a surface of the substrate and in a concave portion formed on the surface of the substrate by performing a cycle a predetermined number of times under a first temperature, the cycle including supplying a precursor gas to the substrate, supplying a first nitrogen- and hydrogen-containing gas to the substrate, and supplying a second nitrogen- and hydrogen-containing gas to the substrate, so that an oligomer including an element contained in at least one selected from the group of the precursor gas, the first nitrogen- and hydrogen-containing gas, and the second nitrogen- and hydrogen-containing gas is generated, grown, and flowed on the surface of the substrate and in the concave portion; and
(b) forming a film so as to fill the inside of the concave portion by performing a post-treatment to the substrate, which has the oligomer-containing layer formed on the surface of the substrate and in the concave portion, under a second temperature not less than the first temperature, so that the oligomer-containing layer formed on the surface of the substrate and in the concave portion is modified to form the film.
